(19) United States
(12) Patent Application Publication
(10) Pub. No.: US 2020/0312681 A1
(43) Pub. Date: Oct. 1, 2020

(54) SUBSTRATE PROCESSING APPARATUS

(71) Applicant: ASM IP Holding B.V., Almere (NL)

(72) Inventors: Koji TANAKA, Tokyo (JP); Yuki TAKAHASHI, Tokyo (JP)

(73) Assignee: ASM IP Holding B.V., Almere (NL)

(21) Appl. No.: 16/781,914

(22) Filed: Feb. 4, 2020

Related U.S. Application Data
(60) Provisional application No. 62/825,441, filed on Mar. 28, 2019.

(51) Int. Cl. H01L 21/67; H01L 21/3065; H01J 37/32

(52) U.S. Cl. CPC H01L 21/67069; H01J 37/32366; H01L 21/3065

(57) ABSTRACT

Examples of a substrate processing apparatus includes a susceptor, a shaft supporting the susceptor, a flow control ring surrounding the susceptor while providing a gap with respect to the susceptor, an exhaust duct arranged directly above the flow control ring, a plate disposed above the susceptor, and a chamber surrounding the susceptor, the flow control ring, the exhaust duct, and the plate, and a coupling part coupling the shaft to the chamber, wherein at least a portion of the coupling part is an insulator.

### TECHNICAL FIELD

Examples are described which relate to a substrate processing apparatus.

### BACKGROUND

Capacitively Coupled Plasma (CCP) is widely used in plasma processing. However, parasitic capacity may be produced in the apparatus, and voltages may be applied to some portions which is not intended. Such unintentional voltage application causes power loss. For example, if a strong electric field is produced at portions other than the perimeter of the bevel, uniformity of the plasma may be deteriorated, and/or the etching rate may be decreased.

### SUMMARY

Some examples described herein may address the above-described problems. Some examples described herein may provide a substrate processing apparatus applying plasma processing to a part of the substrate.

In some examples, a substrate processing apparatus includes a susceptor, a shaft supporting the susceptor, a flow control ring surrounding the susceptor while providing a gap with respect to the susceptor, an exhaust duct arranged directly above the flow control ring, a plate disposed above the susceptor, and a chamber surrounding the susceptor, the flow control ring, the exhaust duct, and the plate, and a coupling part coupling the shaft to the chamber, wherein at least a portion of the coupling part is an insulator.

### BRIEF DESCRIPTION OF THE DRAWINGS

The patent or application file contains at least one drawing executed in color.

Copies of this patent or patent application publication with color drawing(s) will be provided by the Office upon request and payment of the necessary fee.

FIG. 1 illustrates a configuration example of a substrate processing apparatus;

FIG. 2 is an enlarged view of the enclosing part;

FIG. 3A is a circuit diagram illustrating one example of an electrical connection;

FIG. 3B is a circuit diagram illustrating another example of an electrical connection;

FIG. 4 illustrates a result of simulation for an electromagnetic field;

FIG. 5 illustrates another result of simulation for an electromagnetic field;

FIG. 6 is a cross-sectional view of a substrate processing apparatus associated with another example; and

FIG. 7 is a cross-sectional view of a substrate processing apparatus associated with yet another example.

### DETAILED DESCRIPTION

A substrate processing apparatus will be described with reference to the accompanying drawings. The same or similar elements may be denoted with the same symbols, and therefore iteration of description may be omitted.

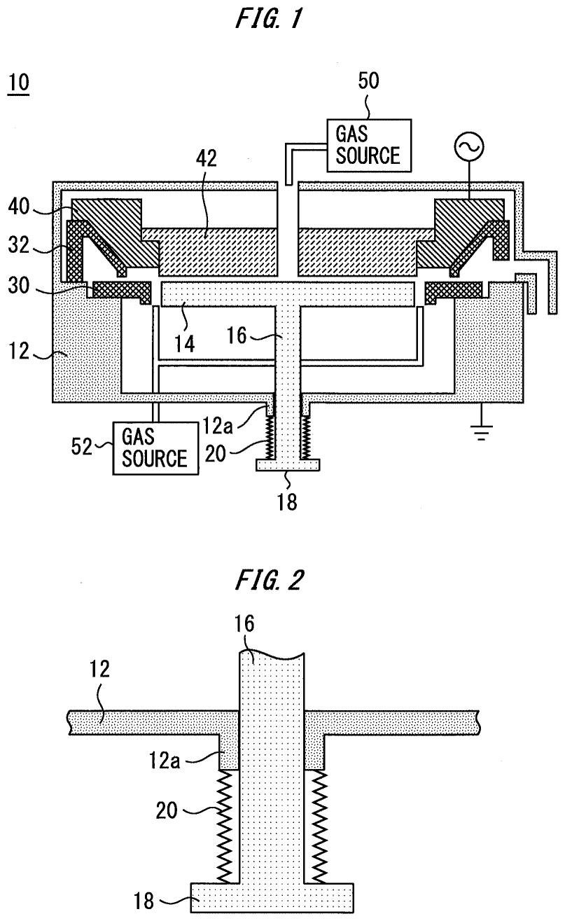

FIG. 1 illustrates a configuration example of a substrate processing apparatus 10. The substrate processing apparatus 10 may be provided as bevel processing apparatus of the substrate. Bevel processing includes bevel etching, bevel depositing, and bevel film reforming. The substrate processing apparatus 10 comprises a chamber 12 functioning as a ground electrode. The chamber 12 is made of metal. In the chamber 12, the substrate to be processing object is placed on a susceptor 14. As the susceptor 14 has smaller geometry than the substrate, the bevel projects from the susceptor 14. In other words, the entirety of the bevel is exposed. The susceptor 14 is made from Al or Ti, for example.

The susceptor 14 is supported by a shaft 16. According to one example, a wide part 18 is provided, which is continuous with and wider than the shaft 16. The wide part 18 may be arranged outside the chamber 12. A part of the chamber 12, which encloses the shaft 16, is referred to as an enclosing part 12a. A bellows 20 is disposed between the enclosing part 12a and the wide part 18. The bellows 20 is stretched and contracted by force from the outside, and thereby the susceptor 14 is lowered and elevated.

FIG. 2 is an enlarged view of the enclosing part 12a and the vicinity of it. The bellows 20 maintain a vacuum inside the chamber 12.

The wide part 18 and the bellows 20 functions as a coupling part coupling the shaft 16 to the chamber 12. For example, at least a portion of the coupling part may be an insulator. According to one example, the wide part 18 may be an insulator. According to another example, the bellows 20 may be an insulator. Such an insulator material may be a low dielectric constant material of which the dielectric constant is less than 10. For example, an insulator is quartz, alumina, or fluorine containing resin. The combination of the wide part 18 and the bellows 20 is one example of the coupling part. In other examples, a coupling part with any configuration may be provided, which enables the susceptor 14 to be lowered and elevated and couples the shaft 16 to the chamber 12.

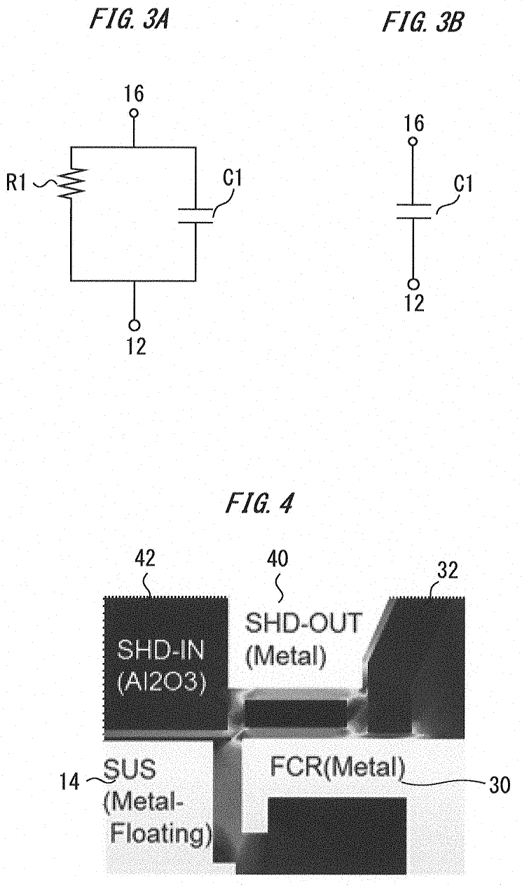

FIGS. 3A and 3B are circuit diagrams illustrating examples of an aspect of an electrical connection between the chamber 12 and the shaft 16. Separating the enclosing part 12a and the shaft 16 causes a capacitor C1. Coupling the shaft 16 and the chamber 12 causes a first resistor R1 attributable to a contact resistance and the like. FIG. 3A shows a circuit including capacitor C1 and first resistor R1. FIG. 3B shows a circuit when at least a portion of the coupling part is made of an insulator.

In this way, separating the enclosing part 12a and the shaft 16 and selecting an insulator as at least a portion of the coupling part enables the susceptor 14 to be in a floating condition. In other words, increasing the impedance value between the susceptor 14 and the chamber 12 separates electrically the susceptor 14 from the chamber 12.

Now going back to describing the configuration in FIG. 1. A flow control ring (FCR) 30 is disposed adjacent to the susceptor 14. The FCR 30 surrounds the susceptor 14, while providing a gap with respect to the susceptor 14. The FCR 30 may be, for example, a metal such as Al or Ti. According to one example, the bottom surface of the FCR 30 is in contact with the chamber 12, thereby the FCR 30 is grounded.

An exhaust duct 32 is arranged directly above the FCR 30. The exhaust duct 32 may be formed circular in planar view, like the FCR 30. The exhaust duct 32 provides a channel for exhausting gas used in a process to the outside of the chamber 12. The exhaust duct 32 may be made of for example ceramic or alumina.

An outer plate 40 is placed on the exhaust duct 32. An inner plate 42 is placed on the outer plate 40. According to one example, the outer plate 40 surrounds the inner plate 42 and is disposed directly above the FCR 30. According to one example, the inner plate 42 is disposed directly above the susceptor 14. A through hole may be disposed at the center of the inner plate 42. The outer plate 40 and the inner plate 42 are sometimes collectively referred to as a plate.

The outer plate 40 and the inner plate 42 compose one plate. They may be separable and may be inseparable. For example, the inner plate 42 is an insulator, and the outer plate 40 is metal. The inner plate 42 may be a low dielectric constant material. The low dielectric constant material is, for example, quartz, alumina, or fluorine containing resin. The outer plate 40 may be an electrode applying a high-frequency wave.

The chamber 12 surrounds the susceptor 14, the FCR 30, the exhaust duct 32, the outer plate 40, and the inner plate 42. Gas sources 50 and 52 are provided outside the chamber 12. According to one example, the gas source 50 supplies a through hole of the inner plate 42 with an inert gas, thereby a radial gas flow arises, which is in planar view between the inner plate 42 and the susceptor 14. The gas flow inhibits significant plasma to be generated between the inner plate 42 and the susceptor 14. And, the gas source 52 supplies a reactive gas from the under side to a gap between the susceptor 14 and the FCR 30. Such gas flows enable the vicinity of the bevel of the substrate to be etched.

Such a gas flow is one example. According to other examples, any gas sources and gas flows may be adopted, which can supply the gas allowing the plasma to be generated in the vicinity of the bevel. Therefore, the gas may be supplied from the upper side, and may be supplied from the under side.

FIG. 4 illustrates a result of simulation for an electromagnetic field in a model in which the susceptor is set floating. In the red area, electric field strength is high, and in the blue area, the electric field strength is low. This simulation adopts a model in which substrate is disposed in a substrate processing apparatus. Applying high-frequency power to the outer plate 40 allows electric field strength in the space between the outer plate 40 and the FCR 30 to be enhanced. On the other hand, because the susceptor is set floating, RF loss with respect to the susceptor 14 is reduced, thereby electric field strength between the susceptor 14 and the inner plate 42 is reduced. Selecting a low dielectric constant material as the inner plate 42 also contributes to reducing the electric field strength between the susceptor 14 and the inner plate 42. Synthetic impedance is more than 500 ohm, of which path is from the plate to the chamber 12 through the susceptor 14, the shaft, and the coupling part, thereby contributes to reduction of abnormal discharge.

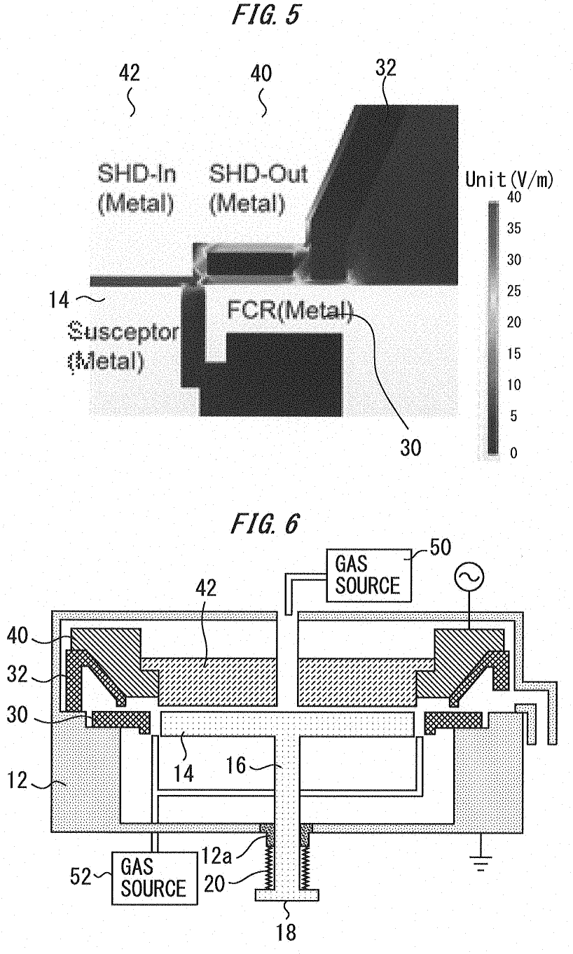

FIG. 5 illustrates, based on the model in FIG. 4, a result of simulation for an electromagnetic field when the inner plate 42 is metal, and the susceptor 14 is a grounded metal. In this case, because a strong electric field is generated between the inner plate 42 and the susceptor 14, abnormal discharge is conceivable.

Thus, a hardware configuration is adopted, that enhances impedance at portions in which it is not intended to have plasma generated. Thereby electric field strength is reduced, and RF is efficiently supplied to an area in which plasma is intended to be generated. A method for reduction of electric field strength includes using a low dielectric constant materials and having floating potential at a relevant part. Configurations FIGS. 1 to 3 are an exemplification. A substrate processing apparatus having a different configuration from FIGS. 1 to 3 may also reduce abnormal discharge and provide stable discharge in a similar way.

FIG. 6 is a cross-sectional view of a substrate processing apparatus associated with another example. In this example, the enclosing part 12a is made up of an insulator, such that the susceptor 14 is floating. The enclosing part 12a is, for example, quartz, alumina, or fluorine containing resin. In this case, the enclosing part 12a is distinguished from the metal chamber 12. Selecting a low dielectric constant material for the enclosing part 12a allows the electrical distance between the metal chamber 12 and the shaft 16 to be widened and the metal chamber 12 and the shaft 16 to be electrically isolated. Accordingly, impedance of the path to the chamber 12 through the susceptor 14 can be further enhanced.

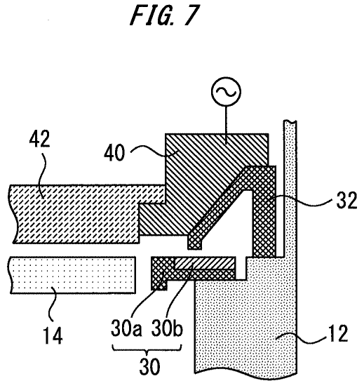

FIG. 7 is a cross-sectional view of a substrate processing apparatus associated with yet another example. The FCR 30 comprises the metal part 30a contacting with the chamber 12 and the insulator part 30b placed directly under the exhaust duct 32. According to one example, the metal part 30a and the insulator part 30b are exposed at the top surface of the FCR 30, and only the metal part 30a is exposed at the bottom surface of the FCR 30. The top surface of FCR 30 may be planer surface so as not to interfere with gas flow to the exhaust duct 32. For example, the insulator part 30b is quartz, alumina, or fluorine containing resin.

The exhaust duct 32 is an insulator. The material of the exhaust duct 32 is, for example, quartz, alumina, or fluorine containing resin.

Coupling the outer plate 40 and the FCR 30 with low impedance provides this path with radio-frequency energy efficiently. However, generation of a high electric field between the FCR 30 and exhaust duct 32 causes high concentration of plasma at this portion. Therefore, as described above, the insulator part 30b is disposed at the FCR 30. Thereby while the outer plate 40 and the FCR 30 are coupled with low impedance, the impedance of the exhaust duct 32 and the FCR 30 may be enhanced. Thereby, discharge at a portion directly under the exhaust duct 32 may be reduced.

When the plate is placed above the susceptor 14 and FCR 30, the impedances may be defined by the following,

(1) a first impedance which is an impedance of a path running through the plate and the susceptor 14,

(2) a second impedance which is an impedance of a path running through the plate and the FCR 30, and

(3) a third impedance which is an impedance of a path running through the exhaust duct 32.

According to one example, the second impedance of the first to the third impedances may be minimized. Thereby, generating local plasma between the outer plate 40 and the FCR 30 allows for plasma processing of the bevel of the substrate.

For example, where the distance between the inner plate 42 and the susceptor 14 is d₁, the area of opposing the inner plate 42 and the susceptor 14 is S₁, the dielectric constant of a material placed between the inner plate 42 and the susceptor 14 is ε₁, and the plasma excitation frequency applied to the outer plate 40 is f₁, the first impedance d₁/2πf₁ε₁S₁ may be set higher than 50 ohm. In order to realize this, for example, quartz and the like may be adopted as the inner plate 42, or d1 and S1 may be adjusted. Note that where f₁ is 13.56 MHz and ε₁ is the dielectric constant of the air, d₁/S₁ is set higher than 0.3777.

For example, where the distance between the exhaust duct 32 and the FCR 30 is d₂, the area of opposing the exhaust duct 32 and the FCR 30 is S₂, the dielectric constant of a material placed between the exhaust duct 32 and the FCR 30 is ε₂, and the plasma excitation frequency applied to the outer plate 40 is f₂, the third impedance d₂/2πf₂ε₂S₂ may be set higher than 50 ohm. In order to realize this, for example, quartz may be adopted as the exhaust duct 32, d₂ and S₂ may be adjusted, or quartz may be adopted as the insulator part 30b in FIG. 7. Note that where f₂ is 13.56 MHz and ε₂ is the dielectric constant of the air, d₂/S₂ is set higher than 0.3777. Another third impedance which is an impedance of a path running through the exhaust duct 32 and chamber 12 may be set higher than 50 ohm.

According to another example, d₁/2πf₁ε₁S₁ may be set higher than 500 ohm, d₂/2πf₂ε₂S₂ may be set higher than 500 ohm, and another third impedance may be set higher than 500 ohm. In other examples, other values may be selected.

Thus, while the first impedance and the third impedance are set to high values, the second impedance is, for example, set to less than 50 ohm, thereby sufficient plasma may be generated between the outer plate 40 and the FCR 30. A portion with potential abnormal discharge varies by the configuration of the apparatus. Accordingly, any configuration may be adopted, in which impedance in the space where the bevel is placed is set low, and impedance in other spaces is set high.

1. A substrate processing apparatus comprising:
a susceptor;
a shaft supporting the susceptor;
a flow control ring surrounding the susceptor while providing a gap with respect to the susceptor;
an exhaust duct arranged directly above the flow control ring;
a plate disposed above the susceptor; and
a chamber surrounding the susceptor, the flow control ring, the exhaust duct, and the plate; and
a coupling part coupling the shaft to the chamber, wherein at least a portion of the coupling part is an insulator.

2. The substrate processing apparatus according to claim 1, wherein the coupling part is comprising a wide part and a bellows, wherein the wide part is continuous with and wider than the shaft and arranged outside the chamber, the bellows is disposed between an enclosing part and the wide part, the enclosing part encloses the shaft in the chamber.

3. The substrate processing apparatus according to claim 1, wherein the insulator is quartz, alumina, or fluorine containing resin.

4. The substrate processing apparatus according to claim 1, wherein the plate comprises an inner plate and an outer plate, the inner plate is disposed directly above the susceptor and is an insulator, the outer plate surrounds the inner plate and is disposed directly above the flow control ring and is metal.

5. The substrate processing apparatus according to claim 1, wherein synthetic impedance of a path is more than 500 ohm, the path is from the plate to the chamber through the susceptor, the shaft, and the coupling part.

6. The substrate processing apparatus according to claim 1, wherein the insulator encloses the shaft and is disposed between the chamber and the shaft.

7. A substrate processing apparatus comprising:
a susceptor;
a flow control ring surrounding the susceptor while providing a gap with respect to the susceptor;
an exhaust duct arranged directly above the flow control ring;
a plate disposed above the susceptor; and
a chamber surrounding the susceptor, the flow control ring, the exhaust duct, and the plate,
wherein the flow control ring includes the metal part being in contact with the chamber and an insulator part placed directly under the exhaust duct.

8. The substrate processing apparatus according to claim 7, wherein the metal part and the insulator part are exposed at a top surface of the flow control ring, and only the metal part is exposed at a bottom surface of the flow control ring.

9. The substrate processing apparatus according to claim 7, wherein the exhaust duct is an insulator.

10. The substrate processing apparatus according to claim 7, wherein the insulator part is quartz, alumina, or fluorine containing resin.

11. A substrate processing apparatus comprising:
a susceptor;
a flow control ring surrounding the susceptor while providing a gap with respect to the susceptor;
an exhaust duct arranged directly above the flow control ring;
a plate disposed above the susceptor and the flow control ring; and
a chamber surrounding the susceptor, the flow control ring, the exhaust duct, and the plate,
wherein a first impedance is an impedance of a path running through the plate and the susceptor, a second impedance is an impedance of a path running through the plate and the flow control ring, a third impedance is an impedance of a path running through the exhaust duct and the flow control ring, and the second impedance of the first to the third impedances is minimized.

12. The substrate processing apparatus according to claim 11,
wherein a distance between the plate and the susceptor is d₁, an area of opposing the plate and the susceptor is S₁, a dielectric constant of a material placed between the plate and the susceptor is ε₁, and a plasma excitation frequency applied to the plate is f₁, and d₁/2πf₁ε₁S₁ is set higher than 50 ohm, and
wherein a distance between the exhaust duct and the flow control ring is d₂, an area of opposing the exhaust duct and the flow control ring is S₂, a dielectric constant of a material placed between the exhaust duct and the flow control ring is ε₂, and a plasma excitation frequency applied to the plate is f₂, and d₂/2πf₂ε₂S₂ is set higher than 50 ohm.

13. The substrate processing apparatus according to claim 12,
wherein the d₁/2πf₁ε₁S₁ is set higher than 500 ohm, and the d₂/2πf₂ε₂S₂ is set higher than 500 ohm.
